(19) United States
(12) Patent Application Publication
(10) Pub. No.: US 2014/0175519 A1
(43) Pub. Date: Jun. 26, 2014

(54) METHOD AND LAYER STRUCTURE FOR PREVENTING INTERMIXING OF SEMICONDUCTOR LAYERS

(71) Applicant: IQE KC, LLC, Taunton, MA (US)

(72) Inventors: Kevin S. Stevens, Cambridge, MA (US); Eric M. Rehder, Los Angeles, CA (US); Charles R. Lutz, Seekonk, MA (US)

(73) Assignee: IQE KC, LLC, Taunton, MA (US)

(21) Appl. No.: 14/076,068

(22) Filed: Nov. 8, 2013

Related U.S. Application Data
(63) Continuation of application No. 13/231,163, filed on Sep. 13, 2011, now abandoned.
(60) Provisional application No. 61/384,094, filed on Sep. 17, 2010.

(51) Int. Cl. H01L 27/06; H01L 29/778; H01L 29/737; H01L 21/02

(52) U.S. Cl. CPC H01L 27/0623; H01L 21/02546; H01L 29/7786; H01L 29/737
USPC 257/195; 438/478

(57) ABSTRACT

A semiconductor device includes an etch-stop layer between a first layer of a field-effect transistor and a second layer of a bipolar transistor, each of which includes at least one arsenic-based semiconductor layer. A p-type layer is between the second layer and the etch-stop layer, and the device can include an n-type layer deposited between the etch-stop layer and p-type layer. The p-type layer provides an electric field that inhibits intermixing of the InGaP layer with layers in the first and second layers.

### RELATED APPLICATION(S)

This is a continuation of U.S. application Ser. No. 13/231,163, filed Sep. 13, 2011, which claims the benefit of U.S. Provisional Application No. 61/384,094, filed on Sep. 17, 2010.

The entire teachings of the above application(s) are incorporated herein by reference.

### BACKGROUND OF THE INVENTION

Doping Gallium Arsenide (GaAs) heavily n-type is known to generate defects which can move throughout semiconductor layers. These defects can move out of the semiconductor layer from which they originate into all other layers in a stack of semiconductor layers. Upon moving into other layers, these defects can cause mixing of these other layers and their dopant profiles. This intermixing of layers and dopant profiles is undesirable because it can modify material properties including bandgap, conductivity, and etch rate relative to the unmixed layers. Therefore a way to prevent intermixing would be of great benefit.

Indium gallium phosphide (InGaP) and arsenic-based layers (e.g., GaAs, AlAs, InAs layers and all their combinations—such as AlGaAs, InGaAs, AlInAs, etc.) typically undergo severe intermixing of the group V elements (phosphorous (P) and arsenic (As)) during epitaxial growth when heavily doped n-type (e.g., >1e18 cm⁻³) GaAs is placed anywhere in the semiconductor layer stack. There is also dopant diffusion and group III intermixing present. InGaP and InAlGaAs layer stacks have multiple applications (etch-stop layers for semiconductor device fabrication and distributed Bragg reflector (DBR) stacks for optical applications are two of many examples) where such diffusion and intermixing is highly detrimental to the processing and/or functioning of the semiconductor device.

Typical semiconductor devices are fabricated by the deposition of semiconductor layers in a controlled manner, often by techniques such as metalorganic chemical vapor deposition (MOCVD) or molecular beam epitaxy (MBE). These layers may consist of constant composition and doping, or they may contain gradients and/or discontinuities in either or both of these. Often, pluralities of layers are fabricated in sequence, forming a stack of semiconductor layers designed to achieve certain electrical, optical, or other functions. Herein, the term “layer” refers to a region of semiconductor material with finite thickness and at least one level of composition and doping density. A “stack,” “layer stack,” or “layer structure” refers to a plurality of layers and therefore may also contain more than one composition or doping density.

There is very high wet etch selectivity between (Al, In)GaAs layers and InGaP which allows for a high degree of control during the device fabrication process. However, if the material in these layers becomes mixed with each other, this wet etch selectivity is lost. An InGaP etch-stop significantly mixed with arsenic-based layers can become difficult to etch at all. In other cases, depending on etch chemistry and layer thicknesses, a mixed InGaP etch stop can be removed (etched) unintentionally, thus failing to serve its intended purpose as an etch-stop.

One such example of using InGaP and InAlGaAs layer combinations for etch-stops exists when a bipolar transistor structure is grown over a field-effect transistor (FET) structure. By combining the advantages of bipolar and field-effect transistors in the same monolithic circuit, these structures can address the demands for greater circuit functionality with minimal increase to die size. A specific example of such a device is Bipolar-High Electron Mobility Transistor (BiHEMT), in which a Heterojunction Bipolar Transistor (HBT) structure is grown on top of a High Electron Mobility Transistor (HEMT) structure. The HBT is a specific type of bipolar transistor and the HEMT is a specific type of FET, each with associated advantages. The HBT is advantageous due to its high gain and low base current and the HEMT is advantageous due to high channel electron velocity and associated high frequency performance. Specific types of HEMT devices include pseudomorphic HEMT (pHEMT) or metamorphic HEMT (mHEMT). Both pHEMT and mHEMT are subsets of HEMTs, just as HEMTs are a subset of FETs, as will be readily understood by those of skill in the art. BiHEMT circuits are attractive for many applications such as in wireless handsets and wireless local area networks. For example, power amplifier circuits and switches can be integrated in a BiHEMT chip instead of having a separate power amplifier circuit in an HBT structure and a separate switch circuit in a HEMT structure.

The thickness and doping level of GaAs contact layers contained in a BiHEMT semiconductor layer structure generally are sufficient to cause severe intermixing of the InGaP etch-stop layer with surrounding arsenic-based (GaAs, AlAs, InAs, AlGaAs, InGaAs, AlInAs, AlInGaAs) layers during layer formation by MOCVD or MBE. This makes etching of the InGaP etch-stop and surrounding layers very difficult to control. Etch-stop layers can exist in multiple locations in a BiHEMT structure. The most common locations are between the HEMT and HBT layer structures and/or in the HEMT structure just above the Schottky layer. For the former, the etch-stop layer is used during a wet etch process to selectively remove the HBT layers in desired locations, uncovering the underlying HEMT structure for subsequent processing. For the latter, once the HEMT structure has been uncovered, the etch-stop layer is used to selectively remove contact or other optional layers from the HEMT in order to locate the Schottky contact (also sometimes called the gate contact) on the Schottky layer at the desired distance from the HEMT channel. This distance is critical to control, for example, the pinchoff voltage of the HEMT.

A mixture of phosphoric acid: H₂O₂: H₂O is a common etchant for GaAs and AlGaAs which does not etch InGaP. HCl is a common InGaP etchant which does not etch GaAs or AlGaAs. However, if InGaP layers become mixed with surrounding As-containing layers, then either the HCl will not be able to remove the InGaP, or the phosphoric acid mix will etch through the InGaP (due to its defective nature) depending upon the thickness of the InGaP layer and the exact concentrations of acid. It should be understood that other wet etch combinations will have similar problems with intermixed InGaP etch-stop layers. Both of these types of failures will prevent the fabrication of a properly functioning BiHEMT device.

For the case of an etch-stop separating HEMT and HBT layers, unintentional removal of the etch-stop (e.g., with the phosphoric acid mix) will lead to undesired etching of HEMT contact layers and can degrade HEMT properties such as contact resistance. If the etch-stop wet etch (e.g., HCl) is unable to remove the etch-stop, subsequent HEMT processing steps that rely on absence of the InGaP etch stop layer, such as ohmic contact formation or recess etching, will be impacted.

For the case of an etch-stop that is used to create a gate recess and locate the Schottky contact of a HEMT, InGaP intermixing with surrounding arsenic-based layers can cause multiple problems. Unintentional removal of the etch-stop (e.g., with the phosphoric acid mix) will lead to undesired etching of HEMT layers below the Schottky layer. These can include the channel and spacer layers, which house the electrons that carry current through the HEMT structure. If the electron concentration in these layers is reduced or if the layers are completely removed, the drain current of the HEMT will be much lower than desired. If the etch-stop wet etch (e.g., HCl) is unable to remove the etch-stop, the Schottky contact will be placed on the surface of the intermixed etch-stop layer, not the Schottky layer as desired. Since the composition of the etch-stop and Schottky layers is different, and since the intermixed etch-stop layer is highly defective, properties of the Schottky contact are degraded. Specifically, this leads to a shift in pinchoff voltage and can also be accompanied by increased leakage or gate nonideality.

Additionally, the growth of HBT layers over HEMT layers by MOCVD or MBE causes dopant profiles (usually silicon) in HEMT layers to become smeared and/or broadened. Proper placement of these dopants is critical, for example, to the on-resistance, pinchoff voltage, and breakdown voltage of the HEMT device contained within the BiHEMT. One or both of the degradation mechanisms described herein (InGaP mixing and dopant profile smearing/broadening) can take place simultaneously and both lead to poor performance of the HEMT device. For the above reasons, there is a need for methods of depositing semiconductor layers which prevent InGaP layer mixing and dopant profile broadening.

### SUMMARY OF THE INVENTION

The invention generally is directed to a semiconductor device and a method of fabricating a semiconductor device.

In one embodiment, the semiconductor device includes a field-effect transistor that includes a first layer of at least one arsenic-based semiconductor, and a bipolar transistor that includes a second layer of at least one arsenic-based semiconductor. An etch-stop is between the first and second layers. A p-type layer is between the etch-stop layer and the second layer, whereby the p-type layer inhibits intermixing of the etch-stop layer with at least one of the arsenic-based semiconductor layers.

In another embodiment, the semiconductor device includes a field-effect transistor that includes a first layer of at least one arsenic-based semiconductor and an etch-stop layer, and a bipolar transistor that includes a second layer of at least one arsenic-based semiconductor. A p-type layer is between the etch-stop layer and the second layer, whereby the p-type layer inhibits intermixing of the etch-stop layer with at least one of the arsenic-based semiconductor layers.

In another embodiment, the invention is a method of fabricating a semiconductor device that includes the steps of depositing a field-effect transistor that includes a first layer of at least one arsenic-based semiconductor and an etch-stop layer, depositing a bipolar transistor that includes a second layer of at least one arsenic-based semiconductor, wherein the etch-stop layer is between the first and second layers, and depositing a p-type layer between the etch-stop layer and the second layer, whereby the p-type layer inhibits intermixing of the etch-stop layer with at least one of the arsenic-based semiconductor layers.

In another embodiment, the invention is a method of fabricating a semiconductor device that includes the steps of depositing an etch-stop layer above an arsenic-based semiconductor layer of a field-effect transistor, depositing a p-type layer above the etch-stop layer, and depositing an arsenic-based semiconductor layer of a bipolar transistor above the p-type layer, thereby creating an electric field that prevents intermixing of the etch-stop layer with at least one of the arsenic-based semiconductor layers.

The invention has many advantages. For example, the semiconductor device of the invention includes a doped p-type semiconductor layer that prevents intermixing of an etch-stop layer and arsenic-containing semiconductor layers. By the same mechanism, it also reduces dopant profile broadening. In one embodiment, the p-type layer is deposited between the etch-stop layer in question and some or all of an n-type layer where defects that lead to intermixing originate.

In a specific example, a heavily p-type doped layer is GaAs, doped with carbon (C) to >3×10¹⁹ cm⁻³ and >12 Å thick. This layer is deposited underneath an n-type GaAs (doped with silicon) subcollector contact layer of an HBT, but deposited above the n-type GaAs contact layer of an FET. Embodiments of the present invention work even if there are layers between the p-type GaAs layer and the n-type GaAs contact layers.

It is believed that the p-type semiconductor layer and the n-type semiconductor layer set up a defect-blocking electric field, which subsequently blocks the defects from reaching the etch-stop layer and therefore prevents mixing of the etch-stop layer with adjacent layers. This also prevents dopant profile broadening for layers in the vicinity of the InGaP layer as well.

Those skilled in the art will appreciate that embodiments of the present invention include other means of setting up an electric field pointing in the proper direction for blocking the defects. Such electric fields are the result of electrostatic charge balance in semiconductor stacks and can be engineered in many ways. For example, a modulation doped heterojunction (n+AlGaAs/undoped InGaAs) may set up a strong electric field in the proper direction which could block charged migrating defects.

### BRIEF DESCRIPTION OF THE DRAWINGS

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

FIG. 1 is an example of a layer structure to prevent intermixing of an InGaP etch-stop layer.

FIG. 2 shows high resolution secondary ion mass spectroscopy (SIMS) data for a 50 Å-thick InGaP etch-stop layer in a HEMT layer structure with and without a heterojunction bipolar transistor (HBT) semiconductor layer structure grown on top.

FIG. 3 shows high resolution SIMS data for the InGaP etch-stop layer in two identical HEMT semiconductor layer structures. There are no HBT layers grown on top of either structure. However, one structure is annealed identically to the time and temperature of HBT layer deposition (however, no HBT layers were deposited).

FIG. 4 shows high resolution SIMS data for the InGaP etch-stop layer in three semiconductor layer structures: One is for an HEMT-only structure, another is for a standard FET with HBT on top structure (i.e., a BiHEMT), and another is for a FET with HBT on top structure with the addition of a p-type layer.

FIG. 5 shows BiHEMT structures processed (a.) with and (b.) without a p-type layer where in (b.) the etch-stop could not be removed and therefore the Schottky contact was placed on the etch-stop instead of on the Schottky layer as desired.

FIG. 6 shows the 2-terminal gate diode current vs voltage (I-V) characteristics of two BiHEMTs which were processed identically and similar data from a stand-alone HEMT with layer structure identical to the HEMT portion of the BiHEMTs.

FIG. 7 shows the transfer curves (drain current vs gate bias) of two BiHEMTs which were processed identically and similar data from a stand-alone HEMT with layer structure identical to the HEMT portion of the BiHEMTs.

FIG. 8 shows the subthreshold curves (log drain current vs. gate bias) of two BiHEMTs which were processed identically and similar data from a stand-alone HEMT with layer structure identical to the HEMT portion of the BiHEMTs.

FIG. 9 shows the common source curves (drain current vs. drain bias at multiple gate biases) of two BiHEMTs which were processed identically and similar data from a stand-alone HEMT with layer structure identical to the HEMT portion of the BiHEMTs.

FIG. 10 shows BiHEMT structures processed (a.) with and (b.) without a p-type layer where in (b.) the etch-stop did not function as an etch-stop, therefore enabling the etchant to remove the Schottky and channel layers and placing the Schottky contact below the channel layer instead of on the Schottky layer as desired.

FIG. 11 shows the transfer curves (drain current vs gate bias) of two BiHEMTs which were processed identically and similar data from a stand-alone HEMT with layer structure identical to the HEMT portion of the BiHEMTs.

FIG. 12 shows the 2-terminal gate diode current vs voltage (I-V) characteristics of two BiHEMTs which were processed identically and similar data from a stand-alone HEMT with layer structure identical to the HEMT portion of the BiHEMTs.

### DETAILED DESCRIPTION OF THE INVENTION

A description of example embodiments of the invention follows.

Embodiments of the present invention relate in general to deposition of semiconductor layers for subsequent fabrication of semiconductor devices, and in particular to methods of controlling intermixing in these layers. These embodiments reduce or prevent undesirable intermixing between InGaP and adjacent layers in Bipolar-High Electron Mobility Transistor (BiHEMT) structures. They can also minimize dopant diffusion related to the intermixing. Those skilled in the art will readily see many other applications for these inventive techniques, such as Distributed Bragg Reflectors (DBRs) in optical devices.

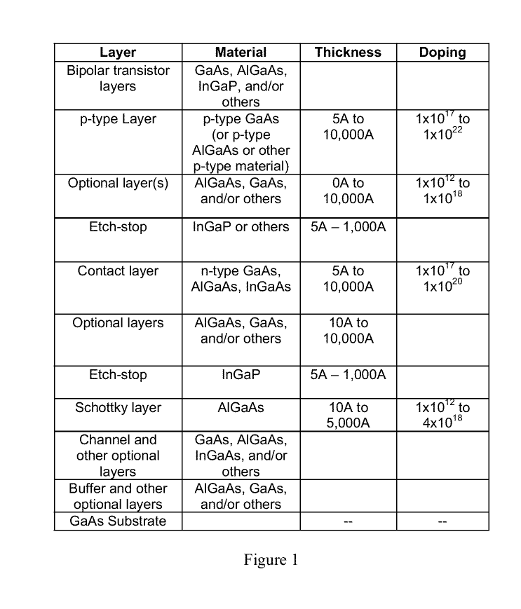

FIG. 1 shows a generic layer structure incorporating a defect blocking layer to prevent mixture of an InGaP layer with the surrounding layers. A p-type establishes a defect-blocking electric field, which blocks the defects from reaching the InGaP layer (etch-stop layer) and therefore prevents mixing of the InGaP layer with adjacent layers. Optional layers may be deposited between the p-type layer and the InGaP layer.

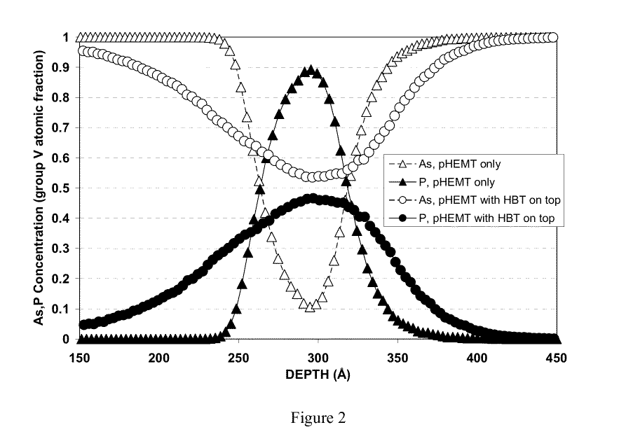

FIG. 2 shows high resolution secondary ion mass spectroscopy (SIMS) data for a 50 Å InGaP etch-stop layer in a HEMT layer structure with and without a heterojunction bipolar transistor (HBT) semiconductor layer structure grown on top. The data consists of arsenic (As) and phosphorous (P) atomic fractions versus depth for both semiconductor layer structures. One can see that the As and P profiles are sharper for the FET-only layer structure as compared to the HEMT with an HBT grown on top. The profiles of the HEMT-only structure are not a perfect step profile due to the resolution limitation of the SIMS measurement. Overall, the data in this plot show how growing an HBT (with heavy n-type doped GaAs subcollector layer) on top of a HEMT structure by techniques such as MOCVD causes the InGaP etch-stop in the HEMT structure to mix with the surrounding arsenic-containing layers.

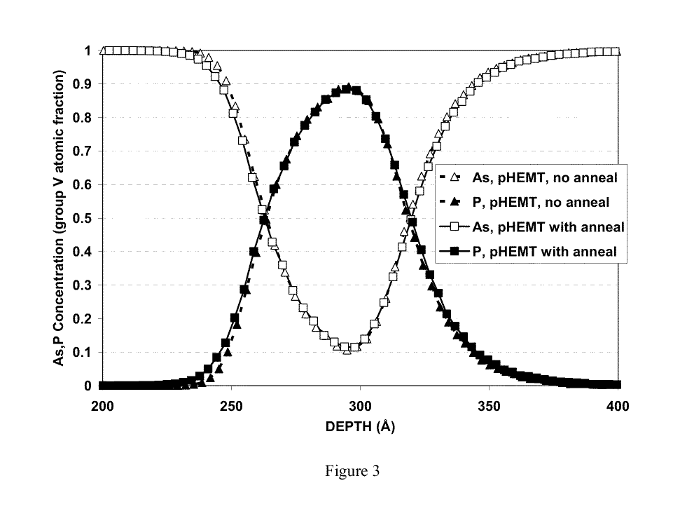

FIG. 3 shows high resolution SIMS data for an InGaP etch-stop layer in two identical HEMT semiconductor layer structures. There are no HBT layers grown on top of either structure. However, one structure is annealed identically to the time and temperature of HBT layer deposition (however, no HBT layers were deposited). The data show how an anneal alone—without the deposition of HBT layers—has very little effect on the As and P profiles. These data show how the actual growth of the HBT layers is needed to cause the As and P mixing in the InGaP etch-stop layer.

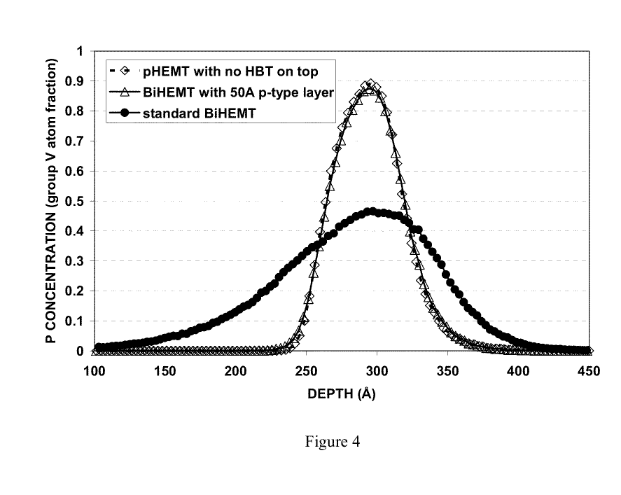

FIG. 4 shows high resolution SIMS data for InGaP etch-stop layers in three different semiconductor layer structures. The first structure is an HEMT-only structure (HEMT), the second structure is a standard HEMT with an HBT on top (standard BiHEMT), and the third structure is a HEMT with an HBT on top and a p-type layer (BiHEMT with 50 Å p-type layer). As in FIG. 2, the HEMT-only layer structure shows much sharper As and P profiles as compared with the standard HEMT with HBT on top layer structure. However, of special note is that the HEMT with HBT on top layer structure with additional p-type layer also shows similarly sharp As and P profiles as the HEMT only layer structure, thus demonstrating that the p-type layer preserves the integrity of the InGaP etch-stop layer, even when a full HBT layer structure is grown on top.

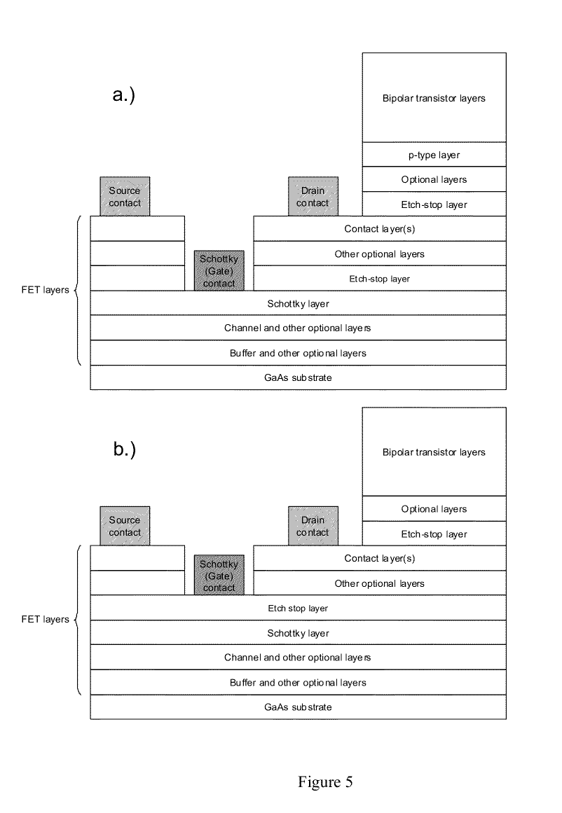

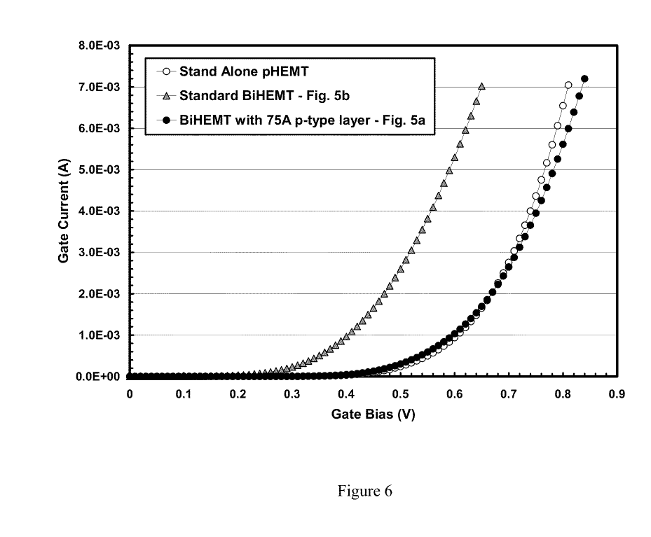

FIG. 5 shows the layer structure and contact locations of devices processed both with (a) and without (b) a p-type layer. For the device shown in FIG. 5(a), the Schottky contact stops on the Schottky layer due to the presence of the p-layer and resultant lack of intermixing. The structure of FIG. 5 (b) shows the Schottky contact stops on the etch-stop layer (due to As/P intermixing, the etch-stop layer was not removable using standard procedures) and resulted in the electrical differences and failures shown in FIGS. 6, 7, 8, and 9.

FIG. 6 shows the forward gate diode current-voltage (I-V) characteristics for three different semiconductor layer structures processed into devices using the identical fabrication process. The first structure is an HEMT-only structure (stand alone HEMT), the second structure is a standard HEMT with an HBT on top (standard BiHEMT), and the third structure is a HEMT with an HBT on top and a p-type layer (BiHEMT with 75 Å p-type layer). The stand alone HEMT data illustrates properly functioning device results for FIGS. 6-9. For FIG. 6 the stand alone HEMT shows a gate diode turn-on voltage of approximately 0.6V. The standard BiHEMT data show a very different gate diode turn-on voltage of approximately 0.4V, because the InGaP etch-stop layer As/P intermixing (FIGS. 2-4) prevented proper removal of the layer prior to Schottky contact formation (illustrated in FIG. 5(b)). However, the BiHEMT with p-type layer results in a gate diode characteristic which is very similar to the stand alone HEMT—thus demonstrating the effectiveness of the p-type layer in preventing As/P intermixing and therefore allowing proper InGaP removal prior to Schottky contact formation (illustrated in FIG. 5(a)).

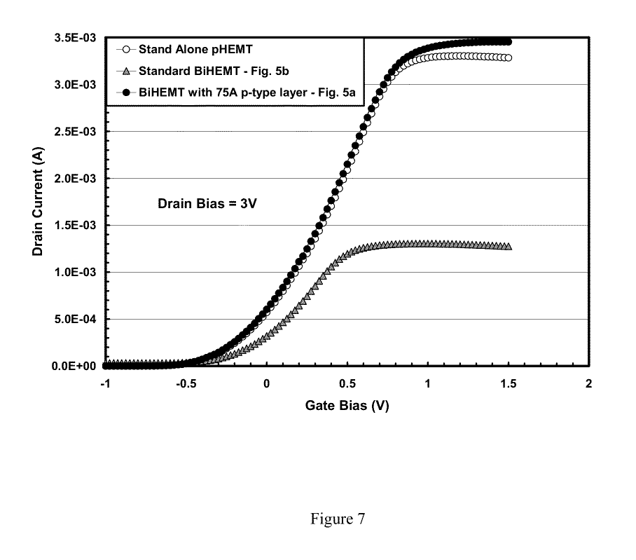

FIG. 7 shows the transfer curves (drain current vs gate bias) of the same three BiHEMTs from FIG. 6 which are processed identically. The BiHEMT with 75 Å p-type layer curve matches the stand alone HEMT data, thus demonstrating that the Schottky gate metal is at the same distance from the HEMT channel for both structures. This was possible for the BiHEMT structure with the p-type layer because the InGaP etch-stop As/P intermixing was prevented, thereby allowing proper removal of the etch-stop layer prior to Schottky contact formation. However, the standard BiHEMT (without any p-type layer) shows a very different looking transfer curve due to the presence of the InGaP etch-stop under the gate Schottky contact. The InGaP was not able to be removed prior to gate Schottky contact formation due to As/P intermixing of the InGaP and surrounding layers. The undesired presence of the InGaP layer moves the gate metal farther away from the channel, thereby greatly reducing the transconductance (as shown in the data).

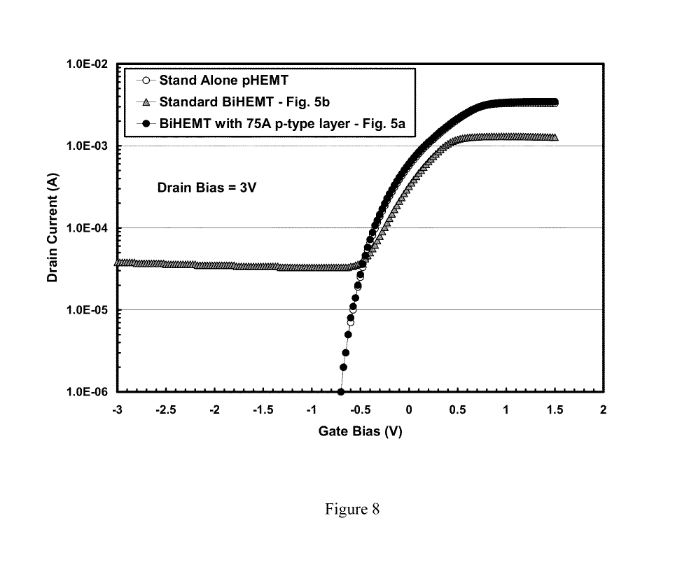

FIG. 8 shows the subthreshold curves (log drain current vs. gate bias) of the same three BiHEMTs from FIGS. 6-7 which are processed identically. Again the stand alone HEMT and BiHEMT with p-type layer curves look very similar, whereas the standard BiHEMT curve (without p-type defect blocking layer) is quite different. In particular, the subthreshold current (drain current value at gate biases <−1V) is much higher for the standard BiHEMT because the gate metal has unremoved InGaP underneath it.

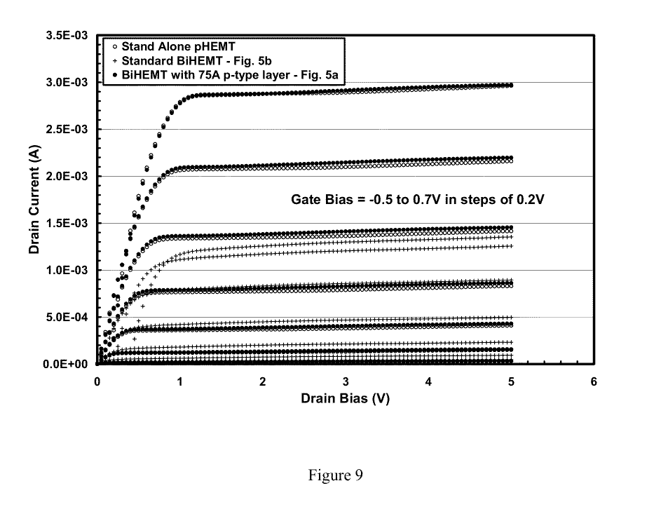

FIG. 9 show the common source curves (drain current vs. drain bias at multiple gate biases) of the same three BiHEMTs from FIGS. 6-8 which are processed identically. Again the stand alone HEMT and BiHEMT with p-type layer curves look very similar, whereas the standard BiHEMT curve (without p-type defect blocking layer) is quite different. In particular, these curves show (as in FIG. 8) that the transconductance of the standard BiHEMT device is degraded, relative to the stand alone HEMT and the BiHEMT with p-type layer. Also, the maximum attainable drain current is greatly degraded for the standard BiHEMT relative to the stand alone HEMT and the BiHEMT with p-type layer. Both these deficiencies in the standard BiHEMT data are due to the undesired presence of the unremoved InGaP etch-stop below the gate metal.

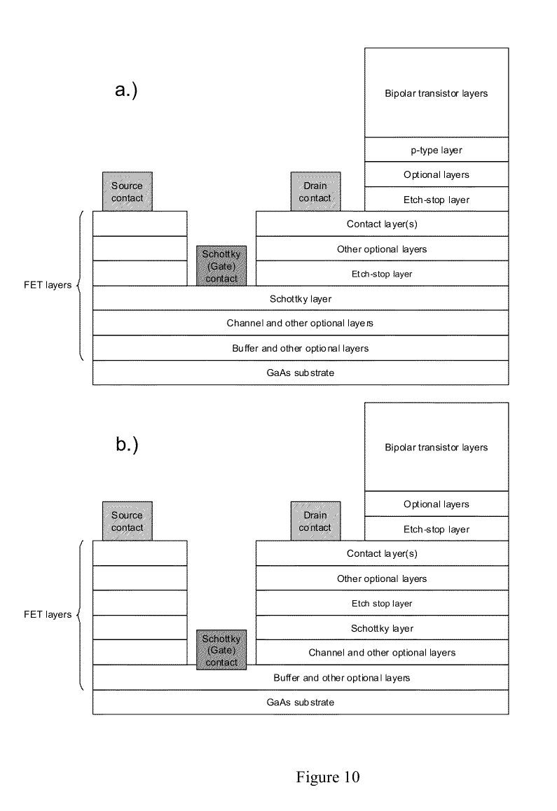

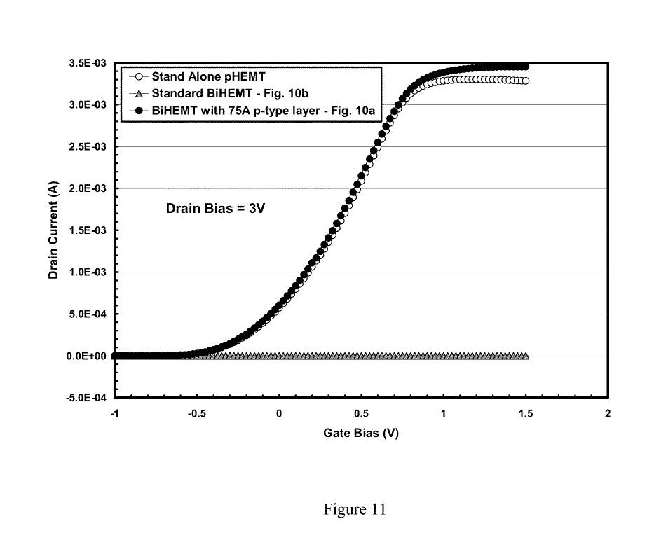

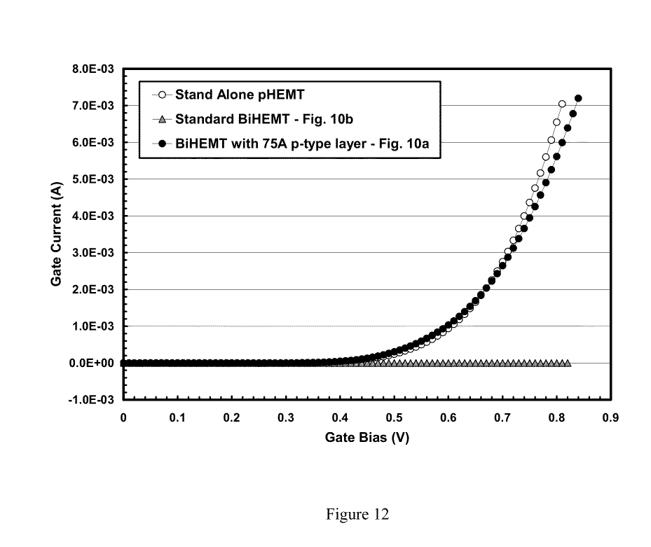

FIG. 10 shows the layer structure and contact locations of devices processed both with (a) and without (b) a p-type layer. For the device shown in FIG. 10(a), the Schottky contact stops on the Schottky layer due to the presence of the p-layer and resultant lack of intermixing. The structure of FIG. 10 (b) shows the Schottky contact was formed below the channel layer (due to As/P intermixing and a thinner etch-stop relative to FIG. 5(b), the etch-stop layer did not exhibit selectivity and was unintentionally removed during the etch of the overlying layers) and resulted in the electrical differences shown in FIGS. 11 and 12.

FIG. 11 shows the transfer curves (drain current vs gate bias) of the BiHEMTs from FIG. 10 compared with the transfer curve of a stand-alone HEMT. All were processed identically. Data from the BiHEMT with p-type layer match the stand alone HEMT data very closely. However, the standard BiHEMT of FIG. 10(b) exhibits extremely low drain current since the etch-stop was removed during wet etching (due to As/P intermixing and a thinner etch-stop relative to FIG. 5(b)) leading to overetch through the etch-stop and channel layers. With the Schottky contact placed below the channel layer, the drain current for the BiHEMT of FIG. 5(b) is much lower than the BiHEMT with p-type layer and the stand-alone HEMT.

FIG. 12 shows the forward gate diode current-voltage (I-V) characteristics of the BiHEMTs from FIG. 10 compared with the diode curve of a stand-alone HEMT. All were processed identically. Data from the BiHEMT with p-type layer match the stand alone HEMT data very closely. However, the standard BiHEMT as shown in FIG. 10(b) exhibits extremely low forward, on-state diode current. This is caused by the fact that the etch-stop was removed during wet etching (due to As/P intermixing and a thinner etch-stop relative to FIG. 10(b)) leading to overetch through the etch-stop and channel layers. With the Schottky contact placed below the channel layer, the diode does not exhibit typical ‘turn-on’ behavior, leading to much lower forward current than the BiHEMT with p-type layer and the stand-alone HEMT.

While this invention has been particularly shown and described with references to example embodiments thereof, it will be understood by those skilled in the art that various changes in form and details may be made therein without departing from the scope of the invention encompassed by the appended claims.

1. A semiconductor device, comprising:
a) a field-effect transistor that includes a first layer of at least one arsenic-based semiconductor and an etch-stop layer;
b) a bipolar transistor that includes a second layer of at least one arsenic-based semiconductor, wherein the etch-stop layer is between the first and second layers; and
c) a p-type layer between the etch-stop layer and the second layer, whereby the p-type layer inhibits intermixing of the etch-stop layer with at least one of the arsenic-based semiconductor layers.

2. The semiconductor device of claim 1, further including an n-type layer between the etch-stop layer and the p-type layer, whereby p-type layer and the n-type layer together are a pn junction.

3. The semiconductor device of claim 2, wherein the n-type layer includes at least one member selected from the group consisting of GaAs, AlGaAs, InGaAs and InGaAsP.

4. The semiconductor device of claim 2, further including at least one additional semiconductor layer between the p-type layer and the n-type layer.

5. The semiconductor device of claim 2, wherein the bipolar transistor is a heterojunction bipolar transistor.

6. The semiconductor device of claim 2, wherein the field-effect transistor is a high electron mobility transistor.

7. The semiconductor device of claim 1, wherein at least one of the first and second layers further includes at least one member of the group consisting of GaAs, AlAs, InAs, AlGaAs, InGaAs and AlInAs.

8. The semiconductor device of claim 1, wherein the etch-stop layer includes phosphorous.

9. The semiconductor device of claim 8, wherein the etch-stop layer consists essentially of InGaP.

10. The semiconductor device of claim 1, wherein the p-type layer includes at least one member of the group consisting of GaAs and AlGaAs.

11. The semiconductor device of claim 1, wherein the p-type layer has a thickness in a range of between about 5 Å and about 10,000 Å.

12. The semiconductor device of claim 11, wherein the p-type layer has a thickness in a range of between about 10 Å and about 1,000 Å.

13. The semiconductor device of claim 12, wherein the p-type layer has a thickness in a range of between about 25 Å and about 500 Å.

14. The semiconductor device of claim 13, wherein the p-type layer has a thickness in a range of between about 50 Å and about 75 Å.

15. The semiconductor device of claim 1, wherein the p-type layer includes at least one dopant selected from the group consisting of carbon, zinc, magnesium, cadmium, and beryllium.

16. The semiconductor device of claim 15, wherein the p-type layer has a dopant concentration in a range of between about 1×10¹⁷ and about 1×10²² per cubic centimeter.

17. The semiconductor device of claim 16, wherein the p-type layer has a dopant concentration in a range of between about 5×10¹⁸ and about 5×10²⁰ per cubic centimeter.

18. A Semiconductor device, comprising:
a) a field effect transistor that includes a first layer of at least one arsenic-based semiconductor;
b) a bipolar transistor that includes a second layer of at least one arsenic-based semiconductor;
c) an etch-stop layer between the first and second layers; and
d) a p-type layer between the etch-stop layer and the second layer, whereby the p-type layer inhibits intermixing of the etch-stop layer with at least one of the arsenic-based semiconductor layers.

19. The semiconductor device of claim 18, further including an n-type layer between the etch-stop layer and the p-type layer, whereby p-type layer and the n-type layer together are a pn junction.

20. The semiconductor device of claim 19, wherein the n-type layer includes at least one member selected from the group consisting of GaAs, AlGaAs, InGaAs and InGaAsP.

21. The semiconductor device of claim 18, further including at least one additional semiconductor layer between the p-type layer and the n-type layer.

22. The semiconductor device of claim 18, wherein the bipolar transistor is a heterojunction bipolar transistor.

23. The semiconductor device of claim 18, wherein the field-effect transistor is a high electron mobility transistor.

24. The semiconductor device of claim 18, wherein at least one of the first and second layers further includes at least one member of the group consisting of GaAs, AlAs, InAs, AlGaAs, InGaAs and AlInAs.

25. The semiconductor device of claim 18, wherein the etch-stop layer includes phosphorous.

26. The semiconductor device of claim 18, wherein the etch-stop layer consists essentially of InGaP.

27. A method of fabricating a semiconductor device, comprising the steps of:
a) depositing an etch-stop layer above an arsenic-based semiconductor layer of a field-effect transistor;
b) depositing a p-type layer above the etch-stop layer; and
c) depositing an arsenic-based semiconductor layer of a bipolar transistor above the p-type layer, thereby creating an electric field that prevents intermixing of the etch-stop layer with at least one of the arsenic-based semiconductor layers.

28. The method of claim 27, further including the step of depositing an n-type layer between the p-type layer and the etch-stop layer.

29. The method of claim 28, further including the step of depositing at least one additional semiconductor layer between the n-type layer and the p-type layer.

30. The method of claim 27, wherein at least one of the arsenic-based semiconductor layers includes at least one member of the group consisting of GaAs, AlAs, InAs, AlGaAs, InGaAs and AlInAs.

31. The method of claim 27, wherein the p-type layer includes at least one member selected from the group consisting of GaAs and AlGaAs.

32. The method of claim 27, wherein the p-type layer has a thickness in a range of between about 5 Å and about 10,000 Å.

33. The method of claim 32, wherein the p-type layer has a dopant concentration in a range of between about 1×10¹⁷ and about 1×10²² per centimeter.

34. The method of claim 27, wherein the layers are deposited by MOCVD or MBE.

35. A method of fabricating a semiconductor device, comprising the steps of:
a) depositing a field-effect transistor that includes a first layer of at least one arsenic-based semiconductor and an etch-stop layer;
b) depositing a bipolar transistor that includes a second layer of at least one arsenic-based semiconductor, wherein the etch-stop layer is between the first and second layers; and
c) depositing a p-type layer between the etch-stop layer and the second layer, whereby the p-type layer inhibits intermixing of the etch-stop layer with at least one of the arsenic-based semiconductor layers.

36. The method of claim 35, further including the step of depositing at least one additional semiconductor layer between the n-type layer and the p-type layer.

37. The method of claim 36, wherein at least one of the arsenic-based semiconductor layers includes at least one member of the group consisting of GaAs, AlAs, InAs, AlGaAs, InGaAs and AlInAs.

38. The method of claim 36, wherein the p-type layer includes at least one member selected from the group consisting of GaAs and AlGaAs.

39. The method of claim 36, wherein the p-type layer has a thickness in a range of between about 5 Å and about 10,000 Å.

40. The method of claim 39, wherein the p-type layer has a dopant concentration in a range of between about 1×10¹⁷ and about 1×10²² per centimeter.

41. The method of claim 35, wherein the layers are deposited by MOCVD or MBE.
